(19) United States
(12) Patent Application Publication
(10) Pub. No.: US 2004/0261713 A1
(43) Pub. Date: Dec. 30, 2004

(54) Monitoring system for plasma deposition facility

(76) Inventors: Jin-Bok Kim, Yongin-si (KR); Jong-Woo Han, Hwasung-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/836,345

(22) Filed: May 3, 2004

(30) Foreign Application Priority Data
Jun. 27, 2003 (KR) 2003-42735

(51) Int. Cl. C23C 16/00

(52) U.S. Cl. 118/723 E

(57) ABSTRACT

A monitoring system for a plasma deposition facility includes a current comparator comparing a sense current with a reference current to generate an error signal and/or a voltage comparator comparing a sense voltage between a cathode electrode and a body of the vacuum chamber with a reference voltage to generate an error signal. A gate unit may be provided to logically combine error signals generated by the current comparator and the voltage comparator to generate a system error signal indicating the presence of contaminate gas within a vacuum chamber in the plasma deposition facility.

### FIELD OF THE INVENTION

The present invention relates generally to a monitoring device for use in conjunction with a semiconductor manufacturing apparatus. More particularly, the present invention relates to a monitoring device adapted to monitor a plasma deposition facility and further adapted to senses the inflow of certain gas(es) during a semiconductor manufacturing process.

### BACKGROUND OF THE INVENTION

Various plasma deposition technique are commonly used in the manufacture of semiconductor devices. Certain plasma deposition techniques have proofed particularly useful in the manufacture of semiconductor devices formed, at least in part, by the application of micro-machining processes. An ionic metal plasma (IMP) facility is typically of the plasma deposition facilities used such applications.

Conventional plasma deposition facilities include a vacuum chamber maintaining a vacuum state in which plasma deposition process(es) are performed. Within this environment, a so-called “target” composed of a metallic material (e.g., Al or Ti) is typically placed in an upper position within the vacuum chamber. A wafer onto which metallic material from the target will be transferred is placed at a lower position within the vacuum chamber. More specifically, a wafer transfer apparatus (e.g., a heater table or a bellows apparatus) adapted to load/unload the wafer in/from the vacuum chamber is installed at the lower position of the vacuum chamber. The wafer is typically placed on a heater table at the lower position of the vacuum chamber.

Within the vacuum chamber, a cathode electrode is formed proximate the target, and a corresponding anode electrode is formed proximate the wafer. If a specific voltage differential is formed between the electrodes, a corresponding electrical field is established between the cathode electrode and anode electrode, and free electrons are emitted from the cathode electrode. The free electrons gain kinetic energy from the electric field and become accelerated electrons.

Argon (Ar) gas is conventionally supplied into the vacuum chamber through a gas supply pipe. Although ionized argon may be supplied, more typically elementary argon is supplied and collides with the accelerated electrons to form argon ion (Ar+). Thus, as the accelerated electrons accelerate from the cathode to the anode electrode(s) in the vacuum chamber, they collide with argon elements or argon ions to form a plasma between the cathode electrode and the anode electrode. Argon ions (Ar+) and electrons (e−) are closely crowded together within the plasma.

Due to the electrical field in the vacuum chamber, argon ions (Ar+) accelerated towards the cathode electrode and collide with the target. The force of such collisions actually fractures off very small portions of the metallic material which falls under the force of gravity from the target to the wafer below. In this general manner, metallic material from the target is deposited onto the wafer.

To prevent a contamination-related processing errors, the vacuum chamber in which the plasma deposition occurs must be isolated from the surrounding atmosphere. However, the plasma deposition facility necessarily includes moving parts, such as bellows, feedthroughs, O-rings and gaskets around piping, etc. Prolonged use of these moving parts ultimately results in some breakdown in their isolating properties and a corresponding gas leakage between the plasma deposition facility and the environment. If leakage occurs during a semiconductor device manufacturing process, contaminating gas are likely to enter the vacuum chamber and result in an increased number of defectives.

For this reason, a residual gas analyzer (RGA) is conventionally used. The RGA regularly analyzes residual gas in the vacuum chamber in order to detect and aid in the suppression of process errors related to contaminating gas inflows. However, the conventional RGA is an expensive piece of equipment and typically requires the use of helium (He), or some other gas, under a high vacuum state. Thus, during certain processing steps characterized by the inflow of one or more gas(es), the resulting pressure is so high that the RGA cannot accurately determine the presence of a contaminating gas.

### SUMMARY OF THE INVENTION

In contrast to the conventional RGA, for example, the present invention provides a monitoring system well adapted to the detection of contaminate gas(es) infiltrating a vacuum chamber during a semiconductor fabrication process involving the formation of a plasma state.

According in one aspect, the present invention provides a monitoring system comprising a current comparator comparing a sense current flowing to the vacuum chamber with a reference current and generating an error signal in relation to a difference between the sense current and the reference current, and a display device displaying an error indication in response to the error signal.

In an analogous aspect, the present invention provides a monitoring system comprising a voltage comparator comparing a sense voltage measured between a cathode electrode and a body of the vacuum chamber with a reference voltage, and generating an error signal in relation to a difference between the sense voltage and the reference voltage, and a display device displaying an error indication in response to the error signal.

In a related aspect, the present invention provides a monitoring system comprising a current comparator comparing a sense current flowing to the vacuum chamber with a reference current and generating a first error signal, a voltage comparator comparing a sense voltage between a cathode electrode and a body of the vacuum chamber with a reference voltage and generating a second error signal, a gate unit logically combining the error signals and generating a system error signal, and a display device displaying an error state indication in response to the system error signal.

### BRIEF DESCRIPTION OF THE DRAWINGS

FIG. 1 is a configuration diagram of a plasma deposition facility monitoring device according to the present invention.

FIG. 2 is a diagram of a vacuum chamber shown in FIG. 1.

FIG. 3 is a diagram of a monitoring device of a plasma deposition facility according to the present invention.

### DESCRIPTION OF THE PREFERRED EMBODIMENT

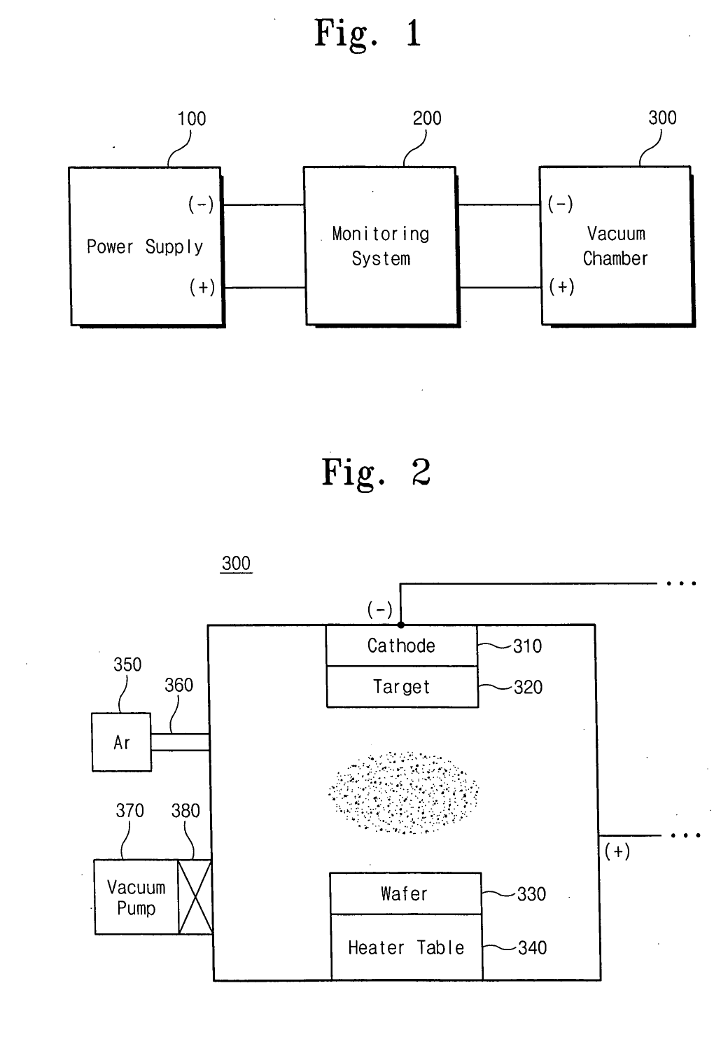

One preferred embodiment of the present invention will now be described in the context of a monitoring device for a plasma deposition facility. This exemplary embodiment is generally shown in FIG. 1.

Referring to FIG. 1, a plasma deposition facility includes a power supply 100, a monitoring system 200, and a vacuum chamber 300. Monitoring system 200 is coupled in series or parallel between power supply device 100 and/or vacuum chamber 300. The structure and operation of monitoring device 200 will be described in some additional detail with reference to FIG. 3.

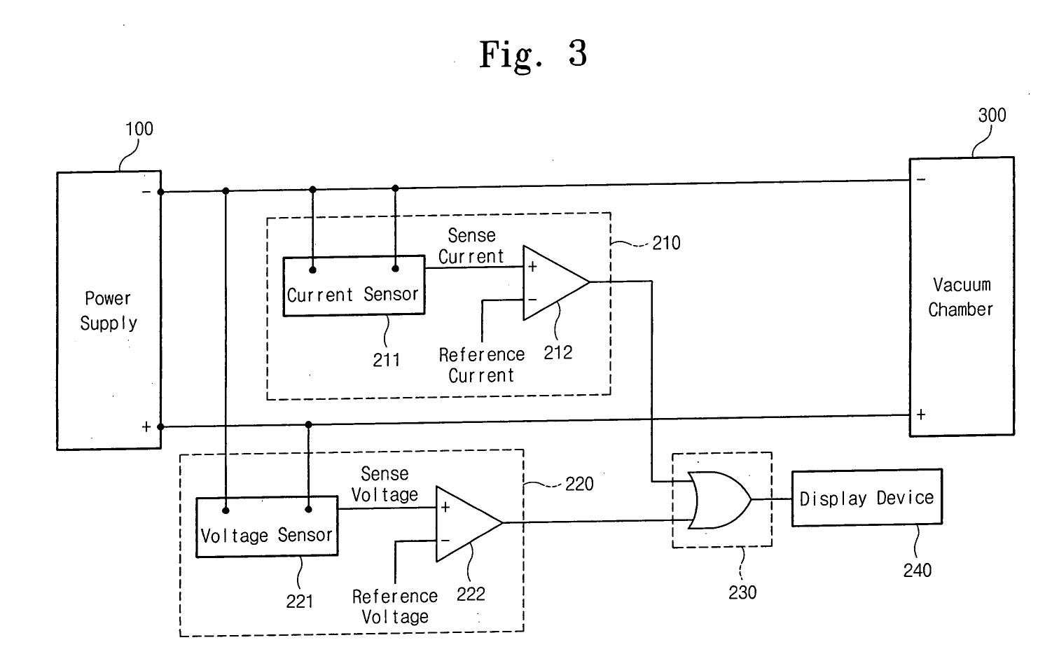

Vacuum chamber 300 is adapted to facilitate the deposition of a metallic material from a target onto a wafer, as generally described above. For this, a negative (−) terminal associated with power supply 100 is coupled to a cathode electrode and a positive (+) terminal associated with power supply 100 is coupled to an anode electrode within the body of vacuum chamber 300. Thereafter, a high voltage differential is formed between the terminals of power supply 100. The structure and operation of vacuum chamber 300 will be described in some additional detail with reference to FIG. 2.

Power supply 100 supplies a direct current (DC) power to the vacuum chamber 300. As presently preferred, a voltage differential of between −350V and −500V is formed by applying a corresponding negative voltage to the negative terminal of power supply 100 and grounding (i.e., maintaining a OV threshold) the positive terminal of power supply 100. When this voltage differential is applied between the cathode electrode and anode electrode, a plasma field is created. Prior to a plasma deposition process and in the absence of any contaminating gas, a voltage and/or a current is detected by monitoring system 200, and defined as a reference voltage and/or a reference current.

The internal structure of the vacuum chamber 300 shown in FIG. 1 is further illustrated in some additional detail in FIG. 2. In one embodiment of the present invention, vacuum chamber 300 is maintained in a vacuum state so as to perform a deposition process. Referring to FIG. 2, a target 320 and a cathode electrode 310 are installed at an upper position of vacuum chamber 300. Target 320 is made of one or more metallic materials (e.g., Al, Ti, etc.) to be deposited onto a wafer 330. Cathode electrode 310 is disposed proximate target 320. An anode electrode corresponding to the cathode electrode 310 is formed in vacuum chamber 300 and may be formed from a portion of the body of vacuum chamber 300. Generally, the anode electrode is grounded. If an appropriate voltage is applied to cathode electrode 310 and the anode electrode, a plasma field develops within vacuum chamber 300. For example, if argon is provided while a DC voltage of between −350V and −500V is applied to cathode electrode 310 and with the anode electrode is grounded, a plasma state develops within vacuum chamber 300 in which argon ions and electrons are closely crowded together.

As shown in FIG. 2, a heater table 340 is installed at a lower position of vacuum chamber 300. Wafer 330 is preferably placed on heater table 340. Heater table 340 in adapted to operate with additional mechanism (not shown) to load and/or unload wafer 330 from vacuum chamber 300.

A gas source 350 and a gas supply pipe 360 are connected at one side of vacuum chamber 300. Argon (Ar) gas used in conjunction with the deposition process is supplied through gas supply pipe 360. Although ionized argon may be supplied, elementary argon is preferably supplied and is ionized within vacuum chamber 300. Vacuum chamber 300 includes a vacuum pump 370 and a valve 380 to enable the formation and release of a vacuum state within vacuum chamber 300. Vacuum pump 370 and value 380 are convention in nature.

An exemplary procedure for creating the plasma state necessary to effect deposition of metallic material onto wafer 330 within vacuum chamber 300 will now be described.

When a specific voltage differential (e.g., −350V to −500V) established between cathode electrode 310 and a grounded anode electrode, an electrical field is formed between cathode electrode 310 and the anode electrode. Under the influence of this electrical field, free electrons are produced proximate target 320, as it is coupled to cathode electrode 310. Due to the electric field, the free electrons gain high kinetic energy and accelerate towards the anode electrode. The argon gas (Ar) supplied through gas supply pipe 360 collides with the accelerated electrons to form argon ions (Ar+). As a result, a plasma field is created in vacuum chamber 300. Within the plasma, argon ions (Ar+) and electrons (e−) are closely crowded together. The argon ions (Ar+) thus formed are accelerated toward cathode electrode 310 under the influence of the electrical field, and collide with considerable force with target 320. Due to the collision force, portions of the metallic material (e.g., Al, Ti, etc.) forming target 320 are fractured off and fall onto wafer 330.

FIG. 3 illustrates monitoring system 200 for the plasma deposition facility in some additional detail. Monitoring system 200 includes a current comparator 210, a voltage comparator 220, a gate unit 230, and a display device 240.

Referring to FIG. 3, current comparator 210 includes a current sensor 211 and an amplifier 212. Current sensor 211 senses current flowing in vacuum chamber 300, in which plasma is created, and outputs a corresponding sense current. Amplifier 212 receives the sense current and a reference current, compares these two current to form a difference signal, and amplifies the difference signal to generate an error signal. Current sensor 211 may take one of several forms, including as an example, a hook on type ammeter that prevents line current from flowing to a conductor and measures the line current. Current sensor 211 is used to measure the sense current flowing in vacuum chamber 300. The reference current value is derived from a sense current measured under controlled conditions in which no contaminate gas has flowed into vacuum chamber 300.

As presently preferred, amplifier 212 is an operational amplifier (OPAMP), which amplifies a difference signal developed between the sense current and the reference current in order to generate a (first) error signal. Both the sense current and the reference current are applied to amplifier 212. The sense current is preferably applied to the non-inverting terminal of amplifier 212, and the reference current is applied to the inverting terminal.

As shown in FIG. 3, voltage comparator 220 includes a voltage sensor 221 and an amplifier 222. Voltage sensor 221 senses a voltage differential between the cathode terminal and an anode terminal of vacuum chamber 300, in which a plasma state is created, in order to generate a sense voltage. Amplifier 222 receives the sense voltage and a reference voltage, compares and amplifies a difference signal developed between the sense voltage and the reference voltage in order to generate a (second) error signal. Voltage sensor 221 is used to measure a voltage between terminals associated with power supply 100. The reference voltage is defined in relation to a sense voltage measured under controlled conditions where the absence of contaminate gas with vacuum chamber 300 is assured. The sense voltage and the reference voltage are applied to amplifier 222. The sense voltage is preferable applied to a non-inverting terminal of amplifier 222, and the reference voltage is applied to an non-inverting terminal.

Gate unit 230 logically combines first and second error signals generated from current comparator 210 and/or voltage comparator 220 to determine an error state, and generate a corresponding system error signal. In one related embodiment of the present invention, gate unit 230 comprises an OR gate and generates an error state indication even if only one of the first and second error signals respectively developed by current comparator 210 or voltage comparator 220 is input to gate unit 230. However, gate unit 230 is needed only in the case where both current comparator 210 and voltage comparator 220 are used at the same time. In a case where only one of the comparators is used, gate unit 230 may be omitted. In this case, respective error signals are directly applied to display device 240.

Display device 240 visually and/or audibly displays the error state when an error signal exceeding a predefined limit is received. Display device 240 may comprise, for example, an alarm or an interlock.

When a contaminate gas flows into vacuum chamber 300 instead of just the desired pure gas, contaminate gas molecules typically attached themselves to the surface of target 320 and form an oxide layer. The presence of this oxide layer causes the sense voltage to drop and the sense current to rise. The monitoring system 200 according to the present invention rapidly senses a change in these values, as compared with nominal operating conditions corresponding to the reference current and reference voltage.

The monitoring system according to the present invention has been described in relation to a plasma deposition facility. However, those of ordinary skill in the art will recognize that a broad class of semiconductor manufacturing facilities and apparatuses adapted to the use of plasma fields, such as for example a sputtering facility or a chemical vapor deposition (CVD) facility, are susceptible to the benefits of the present invention. Further, while the invention has been described in terms of certain presently preferred embodiments, those of ordinary skill in the art will appreciate that various modifications and substitutions may be made without departing from the scope of the claims below, including equivalents thereof.

What is claimed is:

1. A monitoring system for a plasma deposition facility having a vacuum chamber adapted to perform a semiconductor fabrication process, the monitoring system comprising:
a current comparator comparing a sense current flowing to the vacuum chamber with a reference current and generating an error signal in relation to a difference between the sense current and the reference current; and
a display device displaying an error indication in response to the error signal.

2. The monitoring system of claim 1, further comprising: a power supply supplying direct current (DC) power to the vacuum chamber.

3. The monitoring system of claim 1, wherein the current comparator comprises:
a current sensor measuring the sense current; and
an amplifier comparing the sense current and the reference current to determine the difference, and generating the error signal.

4. The monitoring system of claim 3, wherein the amplifier further comprises a non-inverting terminal receiving the sense current and an inverting terminal receiving the reference current.

5. The monitoring system of claim 1, wherein the display device comprises at least one of an alarm and an interlock.

6. The monitoring system of claim 1, wherein the reference current is determined in relation to a sense current measured under controlled conditions wherein no contaminate gas is apparent with the vacuum chamber.

7. The monitoring system of claim 3, wherein the reference current is determined in relation to a sense current measured under controlled conditions wherein no contaminate gas is apparent with the vacuum chamber.

8. A monitoring system for a plasma deposition facility having a vacuum chamber and adapted to perform a semiconductor fabrication process, the monitoring system comprising:
a voltage comparator comparing a sense voltage measured between a cathode electrode and a body of the vacuum chamber with a reference voltage, and generating an error signal in relation to a difference between the sense voltage and the reference voltage; and
a display device displaying an error indication in response to the error signal.

9. The monitoring system of claim 8, further comprising a power supply supplying direct current (DC) power to the vacuum chamber.

10. The monitoring system of claim 8, wherein the voltage comparator comprises:
a voltage sensor measuring the sense voltage; and
an amplifier comparing the sense voltage and the reference voltage to determine the difference and generating the error signal.

11. The monitoring system of claim 10, wherein the amplifier further comprises a non-inverting terminal receiving the sense voltage and an inverting terminal receiving the reference voltage.

12. The monitoring system of claim 8, wherein the display device comprises at least one of an alarm and an interlock.

13. The monitoring system of claim 7, wherein the reference voltage is determined in relation to a sense voltage measured under controlled conditions wherein no contaminate gas is apparent with the vacuum chamber.

14. The monitoring device of claim 11, wherein the reference voltage is determined in relation to a sense voltage measured under controlled conditions wherein no contaminate gas is apparent with the vacuum chamber.

15. A monitoring system for a plasma deposition facility having a vacuum chamber and adapted to perform a semiconductor fabrication process, the monitoring system comprising:
a current comparator comparing a sense current flowing to the vacuum chamber with a reference current and generating a first error signal;
a voltage comparator comparing a sense voltage between a cathode electrode and a body of the vacuum chamber with a reference voltage and generating a second error signal;
a gate unit logically combining first and second error signals and generating a system error signal; and
a display device displaying an error state indication in response to the system error signal.

16. The monitoring system of claim 15, further comprising: a power supply supplying direct current (DC) power to the vacuum chamber.

17. The monitoring device of claim 15, wherein the current comparator comprises:
a current sensor measuring the sense current; and
a first amplifier comparing the sense current and the reference current to determine the difference, and generating the first error signal;
wherein the first amplifier further comprises a non-inverting terminal receiving the sense current and an inverting terminal receiving the reference current; and wherein the voltage comparator comprises:
a voltage sensor measuring the sense voltage; and
a second amplifier comparing the sense voltage and the reference voltage to determine the difference and generating the error signal;
wherein the second amplifier further comprises a non-inverting terminal receiving the sense voltage and an inverting terminal receiving the reference voltage.

18. The monitoring system of claim 15, wherein the display device comprises at least one of an alarm and an interlock.

19. The monitoring system of claim 15, wherein the gate unit comprises an OR gate.

20. The monitoring system of claim 15, wherein the reference current and the reference voltage are respectively a sense current and a sense voltage measured under controlled conditions wherein no contaminate gas is apparent in the vacuum chamber.

21. The monitoring device of claim 17, wherein the reference current and the reference voltage are respectively a sense current and a sense voltage measured under controlled conditions wherein no contaminate gas is apparent in the vacuum chamber.
